(19) United States
(12) Patent Application Publication
(10) Pub. No.: US 2014/0271439 A1
(43) Pub. Date: Sep. 18, 2014

(54) GROUP 13 NITRIDE CRYSTAL AND METHOD FOR PRODUCTION OF GROUP 13 NITRIDE CRYSTAL

(71) Applicants: JUNICHI WADA, MIYAGI (JP); MASAHIRO HAYASHI, MIYAGI (JP); SHINSUKE MIYAKE, SHIGA (JP); NAOYA MIYOSHI, MIYAGI (JP); SEIJI SARAYAMA, MIYAGI (JP)

(72) Inventors: JUNICHI WADA, MIYAGI (JP); MASAHIRO HAYASHI, MIYAGI (JP); SHINSUKE MIYAKE, SHIGA (JP); NAOYA MIYOSHI, MIYAGI (JP); SEIJI SARAYAMA, MIYAGI (JP)

(73) Assignee: RICOH COMPANY, LTD., TOKYO (JP)

(21) Appl. No.: 14/207,931

(22) Filed: Mar. 13, 2014

(30) Foreign Application Priority Data
Mar. 13, 2013 (JP) 2013-051072

(51) Int. Cl. C30B 29/40; C30B 9/10

(52) U.S. Cl. CPC C30B 29/403; C30B 9/10
USPC 423/409; 117/77

(57) ABSTRACT

A group 13 nitride crystal of hexagonal crystal including at least one or more metal atom selected from the group consisting of B, Al, Ga, In, and Tl, and a nitrogen atom, the group 13 nitride crystal comprises: a first region provided on the inner side of a cross section crossing a c-axis; a third region provided on an outermost side of the cross section; a second region provided between the first region and the third region at the cross section and having characteristics different from characteristics of the first region and the third region, wherein a shape formed by a boundary between the first region and the second region at the cross section is non-hexagonal.

### CROSS-REFERENCE TO RELATED APPLICATIONS

The present application claims priority to and incorporates by reference the entire contents of Japanese Patent Application No. 2013-051072 filed in Japan on Mar. 13, 2013.

### BACKGROUND OF THE INVENTION

1. Field of the Invention

The present invention relates to a group 13 nitride crystal, and a method for production of a group 13 nitride crystal.

2. Description of the Related Art

It is known that a gallium nitride (GaN)-based semiconductor material is used as a material which is used for a semiconductor device such as a blue light emitting diode (LED) or white LED, or a semiconductor laser diode (LD: Laser Diode). As a method for production of a semiconductor device using a gallium nitride (GaN)-based semiconductor material, a method is known in which a gallium nitride-based crystal is crystal-grown on a substrate using a MO-CVD method (organic metal chemistry gaseous phase growth method), a MBE method (molecular beam crystal growth method) or the like.

Further, attempts are made to obtain a group 13 nitride crystal of higher quality. For example, a method is disclosed in which a nitride single crystal is crystal-grown from an acicular seed crystal by a flux method to produce a group 13 nitride crystal (see, for example, Japanese Patent Application Laid-open No. 2011-213579 and Japanese Patent Application Laid-open No. 2008-094704). Japanese Patent Application Laid-open No. 2011-213579 discloses that acicular aluminum nitride in which the cross-section shape crossing the c-axis is hexagonal is used as a seed crystal. Japanese Patent Application Laid-open No. 2008-094704 discloses that acicular gallium nitride crystal in which the cross-section shape crossing the c-axis is hexagonal is used as a seed crystal.

However, it has been desired to produce a group 13 nitride crystal of still higher quality.

In view of the situation described above, there is a need to provide a group 13 nitride crystal of high quality.

### SUMMARY OF THE INVENTION

It is an object of the present invention to at least partially solve the problems in the conventional technology.

According to the present invention, there is provided a group 13 nitride crystal of hexagonal crystal comprising at least one or more metal atom selected from the group consisting of B, Al, Ga, In, and Tl, and a nitrogen atom, the group 13 nitride crystal comprising: a first region provided on the inner side of a cross section crossing a c-axis; a third region provided on an outermost side of the cross section; a second region provided between the first region and the third region at the cross section and having characteristics different from characteristics of the first region and the third region, wherein a shape formed by a boundary between the first region and the second region at the cross section is non-hexagonal.

The present invention also provides a method for production of a group 13 nitride crystal, the method comprising a crystal growth step of crystal-growing a nitride crystal in a seed crystal whose cross-section shape crossing a c-axis is non-hexagonal.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIGS. 1(A) and 1(B) are schematic diagrams illustrating one example of a structure of a group 13 nitride crystal of an embodiment of the present invention;

FIG. 2 is a diagram illustrating one example of a group 13 nitride crystal where the cross-section shape crossing the c-axis in a first region is triangular;

FIG. 3 is a schematic diagram where the c-plane of a group 13 nitride crystal is used as a measurement object plane;

FIG. 4 is a schematic diagram illustrating one example of a production apparatus for producing a group 13 nitride crystal to be used as a seed crystal;

FIG. 5 is a schematic diagram of a bulk crystal;

FIG. 6 is a schematic diagram illustrating one example of a production apparatus for producing a bulk crystal and a group 13 nitride crystal;

FIGS. 7(A) and 7(B) are explanatory diagrams of processing of a bulk crystal;

FIGS. 8(A), 8(B), and 8(C) are schematic diagrams illustrating the outline of a method for production of a group 13 nitride crystal;

FIG. 9 is a schematic diagram illustrating one example of rotational drive of a reaction vessel;

FIG. 10 is a schematic diagram illustrating one example of rocking drive of a reaction vessel;

FIG. 11 is a schematic diagram illustrating one example of a group 13 nitride crystal; and

FIG. 12 is a schematic diagram illustrating one example of a comparative group 13 nitride crystal.

### DETAILED DESCRIPTION OF THE PREFERRED EMBODIMENTS

A group 13 nitride crystal and a method for production of a group 13 nitride crystal according to an embodiment of the present invention will be described below with reference to the attached drawings. In the descriptions below, the shapes, sizes and layouts of components are merely schematically illustrated in the figures so that the invention can be understood, and the present invention is not particularly limited thereto.

The group 13 nitride crystal of this embodiment is a hexagonal group 13 nitride crystal including at least one or more metal atom selected from the group consisting of B, Al, Ga, In and Tl, and a nitrogen atom. The group 13 nitride crystal of this embodiment includes a first region, a second region, and a third region. The first region is a region provided on the inner side of a cross section crossing the c-axis. The third region is a region provided on the outermost side of the cross section. The second region is a region which is provided between the first region and the third region at the cross section and has crystal characteristics different from those of the first region and the third region and in which the shape formed by a boundary with the first region at the cross section is non-hexagonal.

As shown in FIGS. 1 and 2, in the group 13 nitride crystal of this embodiment, a second region 25B is provided between a first region 25A on the inner side of a cross section crossing the c-axis and a third region 25C on the outermost side of the cross section in the group 13 nitride crystal. The second region 25B is a transition region for crystal growth. The cross-section shape crossing the c-axis in the first region 25A is non-hexagonal.

Therefore, it is considered that with the group 13 nitride crystal of this embodiment, a group 13 nitride crystal of high quality can be provided.

Specifically, the second region is a region that is formed at the initial stage of crystal growth from a seed crystal in the first region during production of a group 13 nitride crystal. A detailed method for production of a group 13 nitride crystal will be described later. It is considered that at the initial stage of crystal growth, it is difficult to form a crystal having exactly the same characteristics as those of the seed crystal (first region) immediately after the start of growth due to growth conditions, for example a time until stabilization of a crystal growth atmosphere and a seed crystal surface state, etc. It is considered that the way in which impurities are entrapped varies depending on a crystal growth direction. Even when characteristics different from those of the seed crystal (first region) are intentionally grown, dislocations may be concentrated at the initial stage of growth, or a region containing impurities in a large amount may be formed. The second region is considered to be a region which is formed at the initial stage of growth and has concentrated dislocations or has a large amount of impurities due to the above-mentioned factors. That is, the second region is considered to be a region having a large amount of dislocations and impurities as compared to the first region and the third region.

On the other hand, the third region is a region that is formed through the second region during later-described production of a group 13 nitride crystal. Thus, the third region is considered to be a region of good crystal quality with a low dislocation density or less impurities as compared to the second region. This is considered to be because the second region serves as a transition region or buffer region for crystal growth. Accordingly, the third region of good crystal quality can be formed by passing through the second region.

The cross-section shape crossing the c-axis in the first region is non-hexagonal. When the shape of the cross section in the first region is non-hexagonal, the second region is easily formed so as to cover the entire outer periphery of the first region during production of a group 13 nitride crystal as compared to a case where the shape of cross section in the first region is hexagonal.

Thus, in the group 13 nitride crystal of this embodiment, the second region is effectively formed on the periphery of the first region during production of the group 13 nitride crystal. Therefore, it is considered that in this embodiment, a group 13 nitride crystal of high quality can be provided.

The “group 13 nitride crystal of high quality” means that defects such as dislocations in a region on the outermost side of a cross section crossing the c-axis are few as compared to a region on the inner side. The region on the outermost side refers to a partial region being continuous toward the inner side from the outer edge at the cross section crossing the c-axis of the group 13 nitride crystal, and corresponds to the third region. The region on the inner side refers to a region used as a seed crystal at the cross section, and specifically corresponds to the first region.

The details will be described below.

Group 13 Nitride Crystal

The group 13 nitride crystal according to this embodiment is a group 13 nitride crystal of hexagonal structure which includes at least one or more metal atom selected from the group consisting of B, Al, Ga, In and Tl, and a nitrogen atom. The group 13 nitride crystal according to this embodiment preferably includes at least one of Ga and Al, further preferably includes at least Ga as a metal atom.

In this embodiment, the group 13 nitride crystal includes a first region provided on the inner side of a cross section crossing the c-axis, a third region provided on the outermost side of the cross section, and a second region provided between the first region and the third region at the cross section and having crystal characteristics different from those of the first region and the third region. The shape formed by a boundary between the first region and the second region at the cross section is non-hexagonal.

FIGS. 1(A) and 1(B) illustrate one example of a group 13 nitride crystal 25 of this embodiment. Specifically, FIGS. 1(A) and 1(B) are schematic sectional diagrams illustrating one example of a structure of the group 13 nitride crystal of this embodiment. FIG. 1(A) is a schematic diagram illustrating an outer appearance of the group 13 nitride crystal 25 having a crystal structure of hexagonal crystal. FIG. 1(B) illustrates a sectional view where the cross section is orthogonal to the c-axis of the group 13 nitride crystal 25.

As illustrated in FIGS. 1(A) and 1(B), the cross-section shape perpendicular to the c-axis (hereinafter, referred to simply as a c-plane in some cases) in the group 13 nitride crystal 25 is hexagonal. In this embodiment, the hexagon includes regular hexagon and hexagons other than regular hexagon. The side face of the group 13 nitride crystal 25, which corresponds to a side of the hexagon, is formed principally of the m-plane of a crystal structure of hexagonal crystal.

The group 13 nitride crystal 25 in this embodiment is a single crystal, but has a first region 25A, a second region 258, and a third region 25C.

The first region 25A is a region provided on the inner side of a cross section perpendicular to the c-axis in the group 13 nitride crystal 25. The inner side of a cross section perpendicular to the c-axis refers to a region which does not include the outer edge and a region continuous to the outer edge (third region 25C) at the cross section perpendicular to the c-axis and is situated on the inner side with respect to the outer edge and the region continuous to the outer edge (third region 25C).

The cross-section shape crossing the c-axis in the first region 25A is non-hexagonal. The non-hexagon refers to a shape other than hexagons. Specific examples of the cross-section shape crossing the c-axis in the first region 25A include, but are not limited to, triangles, rectangles, pentagons, and circles.

FIG. 1 illustrates one example of the group 13 nitride crystal 25 where the cross-section shape crossing the c-axis in the first region 25A is quadrangular. FIG. 2 illustrates one example of the group 13 nitride crystal 25 where the cross-section shape crossing the c-axis in the first region 25A is triangular. As illustrated in FIGS. 1 and 2, the cross-section shape crossing the c-axis in the first region 25A should be a shape other than hexagons.

The shape of the cross section in the first region 25A is preferably quadrangular among the non-hexagonal cross section shape from the viewpoint of ease of processing when the first region 25A, a region corresponding to a seed crystal, is provided (see FIG. 1(B)).

The third region 25C is a region provided on the outermost side of the c-plane cross section in the group 13 nitride crystal 25 and including the outer edge and a region continuous to the outer edge at the c-plane cross section. That is, the outer periphery of the third region 25C and the outer periphery of the group 13 nitride crystal 25 are identical, and the cross-section shape crossing the c-axis in the third region 25C (the shape of the outer periphery of the cross section) is hexagonal.

The second region 25B is a transition region for crystal growth, which is provided between the first region 25A and the third region 25C, at a cross section perpendicular to the c-axis of the group 13 nitride crystal 25. Specifically, the second region 25B is provided so as to cover the entire outer periphery of the first region 25A at a cross section perpendicular to the c-axis of the group 13 nitride crystal 25.

In this embodiment, a case is described where the c-plane that is a cross section perpendicular to the c-axis of the group 13 nitride crystal 25 includes the first region 25A, the second region 25B, and the third region 25C, but the cross section is not limited to the exact c-plane, and it suffices that at least one of cross sections crossing the c-axis of the group 13 nitride crystal 25 includes the first region 25A, the second region 25B, and the third region 25C.

The crystal characteristic refers to an emission spectrum by excitation with electron beams or ultraviolet light, a dislocation density, and a dislocation direction, which are measured at room temperature. In this embodiment, being different in crystal characteristics means being different in at least one characteristic of the emission spectrum, dislocation density, and dislocation direction.

In this embodiment, the room temperature is generally about 20° C., and specifically refers to 10° C. to 30° C. (inclusive).

An emission spectrum by excitation with electron beams or ultraviolet light is obtained by, for example, measuring a photoluminescence (PL) with a He—Cd laser (helium-cadmium laser) as an excitation light source, but the method is not limited thereto. For example, the color and density of a spectrum may be observed with a fluorescence microscope or the like, followed by identifying a spectrum according to the observed color.

The dislocation density and the dislocation direction are measured in the following manner. For example, the outermost surface of a measurement object plane is etched using a mixed acid of sulfuric acid and phosphoric acid, a molten alkali of KOH and NaOH, or the like to generate etch pits. A picture of the structure of the measurement object plane after etching is taken using an electron microscope, and an etch pit density (EPD) is calculated from the obtained picture. The EPD corresponds to a dislocation density. A detailed method for measurement of a dislocation density will be described later.

As illustrated in FIGS. 1(A) and 1(B), in this embodiment, the second region 25B is provided between the first region 25A and the third region 25C, and the second region 25B is provided so as to cover the entire outer periphery of the first region 25A. That is, the second region 25B lies between the first region 25A and the third region 25C, so that the first region 25A and the third region 25C are in a non-contact state.

Thus, the third region 25C is crystal-grown through the second region 25B from a seed crystal of the first region 25A, so that the third region 25C of better crystal quality is obtained as compared to a case where the cross-section shape crossing the c-axis in the first region 25A is not non-hexagonal.

The “seed crystal of the first region 25A” described above is a seed crystal that is used during production of the group 13 nitride crystal 25. That is, a cross section region perpendicular to the c-axis in the seed crystal used during production of the group 13 nitride crystal 25 corresponds to the first region 25A. A method for production of a group 13 nitride crystal will be described later.

The group 13 nitride crystal 25 of this embodiment should have the first region 25A, the second region 25B, and the third region 25C, and may contain other crystal regions, defects and so on.

Characteristics of Regions

Dislocation Density

Next, dislocations in the crystal will be described.

The dislocation density of dislocations in a direction crossing the c-axis in the second region 25B is preferably higher than that in the first region 25A and the third region 25C. This is because the second region 25B is a transition region for crystal growth as described above. In the second region 258, dislocations are concentrated as compared to other regions as described above, and therefore dislocations overlap one another, leading to disappearance of dislocations. Thus, dislocations in a direction crossing the c-axis in the third region 25C are reduced as compared to those in the second region 25B.

The dislocation density of dislocations in a direction perpendicular to the c-axis (i.e. basal plane dislocations) in the first region 25A is preferably higher than the dislocation density of threading dislocations of the c-plane in the first region 25A.

The basal plane dislocation (BPD) is a dislocation in a direction parallel to the c-plane (plane perpendicular to the c-axis). The threading dislocation of the c-plane is a dislocation in a direction passing through the c-plane. Thus, it can be said that in the first region 25A, dislocations in a direction passing through the c-plane are suppressed.

The dislocation density of the basal plane dislocations and the dislocation density of threading dislocations of the c-plane are measured by the methods described below.

For example, etch pits are generated by etching the outermost surface of a measurement object plane, etc. Mention is made of a method in which a picture of the structure of the measurement object plane after etching is taken using an electron microscope, and an etch pit density is calculated from the obtained picture.

Examples of the method for measurement of a dislocation density include a method for measuring a measurement object plane with cathodoluminescenece (CL) (electron beam fluorescence observation).

For the measurement object plane, for example, the c-plane, the m-plane {10-10}, and the a-plane {11-20} are used.

FIG. 3 is a schematic diagram where the c-plane (c-plane cross section) of the group 13 nitride crystal 25 is used.

As illustrated in FIG. 3, for the c-plane cross section of the group 13 nitride crystal 25, etching is carried out as described above, followed by observation with an electron microscope or cathodoluminescenece. As a result, a plurality of dislocations is observed. Among these dislocations observed at the c-plane cross section, linear dislocations are counted as basal plane dislocations P to calculate a dislocation density of basal plane dislocations P. On the other hand, among the dislocations observed at the c-plane cross section, spotted dislocations are counted as threading dislocations Q to calculate a dislocation density of threading dislocations Q of the c-plane. In the case of cathodoluminescenece, the dislocation is observed as a dark spot or a dark line.

In this embodiment, the spotted dislocation is counted as a “spotted” dislocation when a ratio of the major axis of an observed spotted dislocation to the minor axis of the spotted dislocation is 1 to 1.5 (inclusive). Thus, the shape of the spotted dislocation is not limited to a perfect circle, and those having an elliptical shape are also counted as the spotted dislocation. Further specifically, in this embodiment, dislocations having a major axis of 0.5 μm or less in the observed cross-sectional shape are counted as the spotted dislocation.

On the other hand, in this embodiment, the linear dislocation is counted as a “linear” dislocation when a ratio of the major axis of an observed linear dislocation to the minor axis of the linear dislocation is 4 or more. Further specifically, in this embodiment, dislocations having a major axis of more than 2 μm in length in the observed cross-sectional shape are counted as the linear dislocation.

Production Method

Next, a method for production of the group 13 nitride crystal 25 will be described.

The group 13 nitride crystal 25 includes a crystal growth step of crystal-growing a nitrogen crystal in a seed crystal in which the cross-section shape crossing the c-axis is non-hexagonal.

The first region 25A in the group 13 nitride crystal 25 obtained by crystal-growing a nitride crystal from a seed crystal corresponds to this seed crystal.

For the seed crystal, a group 13 nitride crystal prepared by a publicly known production method is used. Particularly, it is preferable to use, as the seed crystal, one obtained by processing a group 13 nitride crystal (e.g. GaN crystal) formed by crystal-growing an acicular seed crystal so that the cross-section shape crossing the c-axis becomes non-hexagonal.

Since the seed crystal corresponds to the first region 25A, the cross-section shape crossing the c-axis of the seed crystal should be non-hexagonal, and may be triangular, quadrangular, pentagonal, or circular, etc. as described above. Particularly, the cross-section shape crossing the c-axis of the seed crystal is preferably quadrangular as described above.

It is further preferable to use, as the seed crystal, one processed by cutting, along a direction parallel to the c-axis, a group 13 nitride crystal in which the dislocation density of basal plane dislocations is higher than the dislocation density of threading dislocations of the c-plane, so that the cross-section shape crossing the c-axis becomes non-hexagonal.

A crystal growth method to be used in the crystal growth step in the method for production of the group 13 nitride crystal 25 may be a vapor phase growth method or may be a flux method. Particularly, it is preferable to use a later-described flux method for the crystal growth method. Specifically, the crystal growth step is preferably a step of crystal-growing a nitride crystal in a seed crystal by reacting a mixed melt liquid with nitrogen in the melt liquid containing at least one of an alkali metal and an alkali earth metal and at least a group 13 metal.

Next, a method for production of the group 13 nitride crystal 25 using a flux method will be described in detail.

[1] Method for Production of Bulk Crystal Using Seed Crystal

(1) Method for Production of Acicular Seed Crystal

Production Apparatus

FIG. 4 is a schematic view illustrating one example of a production apparatus 1 for an acicular group 13 nitride crystal to be used for a seed crystal of a bulk crystal described later. The acicular group 13 nitride crystal that is produced by the production apparatus 1 is an acicular GaN crystal having a crystal structure of hexagonal crystal. In the acicular GaN crystal, the cross-section shape perpendicular to the c-plane is generally hexagonal. In the descriptions below, the acicular GaN crystal having a crystal structure of hexagonal crystal is referred to as an acicular seed crystal 40. A GaN crystal crystal-grown using the acicular seed crystal 40 or a later-described seed crystal 46 for a seed crystal is referred to as a bulk crystal 41 (identical to “group 13 nitride crystal 25” when the seed crystal 46 is used) (not illustrated in FIG. 4; explained in FIG. 5). The seed crystal of the group 13 nitride crystal 25 is obtained by processing the bulk crystal 41.

The production apparatus 1 includes an external pressure-resistant vessel 28 made of stainless steel. An internal vessel 11 is placed in the external pressure-resistant vessel 28, and further a reaction vessel 12 is stored in the internal vessel 11, thus forming a double structure. The internal vessel 11 is detachably attachable to the external pressure-resistant vessel 28.

The reaction vessel 12 is a vessel which holds a mixed melt liquid 24 formed by melting a raw material and additives, and is intended for producing the acicular seed crystal 40.

Gas supply pipes 27 and 32 for supplying a nitrogen (N₂) gas as a raw material of a group 13 nitride crystal and a diluent gas for adjustment of total pressure to an internal space 33 of the external pressure-resistant vessel 28 and an internal space 23 of the internal vessel 11 are connected to the external pressure-resistant vessel 28 and the internal vessel 11. A gas supply pipe 14 is branched into a nitrogen supply pipe 17 and a gas supply pipe 20, which can be isolated by valves 15 and 18, respectively.

It is desirable to use as a diluent gas an argon (Ar) gas which is an inert gas, but the diluent gas is not limited thereto, and other inert gases such as helium (He) may be used as the diluent gas.

The nitrogen gas is supplied from the nitrogen supply pipe 17 connected to a gas cylinder etc. of nitrogen gas, pressure-adjusted in a pressure controller 16, and then supplied to the gas supply pipe 14 through the valve 15. On the other hand, the diluent gas (e.g. argon gas) is supplied from the diluent gas supply pipe 20 connected to a gas cylinder etc. of diluent gas, pressure-adjusted in a pressure controller 19, and supplied to the gas supply pipe 14 through the valve 18. In this way, the pressure-adjusted nitrogen and diluent gas are each supplied to the gas supply pipe 14 and mixed.

The mixed gas of nitrogen and diluent gas is supplied from the gas supply pipe 14 through valves 31 and 29 to the external pressure-resistant vessel 28 and the internal vessel 11. The internal vessel 11 can be detached from the production apparatus 1 at the valve 29 part. The gas supply pipe 27 communicates with the outside through the valve 30.

The gas supply pipe 14 is provided with a pressure gauge 22, so that the pressures of the insides of the external pressure-resistant vessel 28 and the internal vessel 11 can be adjusted while the total pressures of the insides of the external pressure-resistant vessel 28 and the internal vessel 11 are monitored by the pressure gauge 22.

The production apparatus 1 is configured such that a nitrogen partial pressure can be adjusted by adjusting the pressures of the nitrogen gas and the diluent gas by valves 15 and 18 and pressure controllers 16 and 19 as described above. Since the total pressures of the external pressure-resistant vessel 28 and the internal vessel 11 can be adjusted, the total pressure in the internal vessel 11 increases, and evaporation of a flux (e.g. sodium) in the reaction vessel 12 can be suppressed. That is, a nitrogen partial pressure associated with a nitrogen raw material, which has influences on crystal growth conditions of gallium nitride, and a total pressure having influences on suppression of evaporation of sodium can be controlled separately.

A heater 13 is placed on the outer side of the internal vessel 11 in the external pressure-resistant vessel 28, so that the internal vessel 11 and the reaction vessel 12 are heated to adjust the temperature of mixed melt liquid 24.

For growing a crystal while the concentration of boron in the acicular seed crystal 40 is made different between the inside of the crystal and the outside of the crystal, production of the acicular seed crystal 40 by the production apparatus 1 includes a boron dissolving step in which boron is dissolved in the mixed melt liquid 24, a boron entrapping step in which boron is entrapped in a crystal during crystal growth, and a boron reducing step in which the concentration of boron in the mixed melt liquid 24 is reduced with the process of crystal growth.

In the boron dissolving step, boron is dissolved in the mixed melt liquid 24 from boron nitride (BN) contained in the inner wall of the reaction vessel 12 or a member formed of boron nitride, which is placed in the reaction vessel 12. Next, dissolved boron is entrapped in a crystal that is crystal-grown (boron entrapping step). Then, the amount of boron entrapped in the crystal is gradually reduced with crystal growth (boron reducing step).

According to the boron reducing step, when the acicular seed crystal 40 is crystal-grown while the m-plane ({10-10} plane) is grown, the concentration of boron in the outside region can be lower than the concentration of boron in the inside region at a cross section crossing the c-axis. In this way, the concentration of boron as an impurity and the dislocation density in the crystal, which may be caused by the impurity, are reduced at the outer peripheral surface (six side surfaces of the hexagonal prism) formed of the m-plane of the acicular seed crystal 40, so that the outer peripheral surface of the acicular seed crystal 40 can be formed of a crystal of good quality as compared to the inside region of the acicular seed crystal 40.

Next, the boron dissolving step, the boron entrapping step, and the boron reducing step will be described more in detail.

(i) Method in which the Reaction Vessel 12 Includes Boron Nitride

As an example of the boron dissolving step, the reaction vessel 12 having a sintered body of boron nitride (BN sintered body) as a material is used as the reaction vessel 12. In the process of heating the reaction vessel 12 to a crystal growth temperature, boron is eluted from the reaction vessel 12, and starts to be dissolved in the mixed melt liquid 24 (boron dissolving step). Then, in the process of growth of the acicular seed crystal 40, boron in the mixed melt liquid 24 is entrapped in the acicular seed crystal 40 (boron entrapping step). Boron in the mixed melt liquid 24 is gradually reduced as the acicular seed crystal 40 is grown (boron reducing step).

In the description above, the reaction vessel 12 of a BN sintered body is used, but the configuration of the reaction vessel 12 is not limited thereto. As a preferred embodiment, a substance including boron nitride (e.g. BN sintered body) may be used for at least a part of the inner wall, which is in contact with the mixed melt liquid 24, in the reaction vessel 12, and for other parts of the reaction vessel 12, a nitride such as pyrolytic BN(P—BN), an oxide such as alumina or YAG, a carbide such as SiC, or the like may be used.

(ii) Method in which a Member Including Boron Nitride is Placed in the Reaction Vessel 12

Further, as another example of the boron dissolving step, a member including boron nitride may be placed in the reaction vessel 12. As one example, a member of a BN sintered body may be placed in the reaction vessel 12.

In this method, in the process of heating the reaction vessel 12 to the crystal growth temperature, boron is dissolved little by little in the mixed melt liquid 24 from the member placed in the reaction vessel 12 (boron dissolving step).

Here, in the methods (i) and (ii), a crystal nucleus of a gallium nitride crystal is easily generated on the surface of boron nitride. Therefore, when a crystal nucleus of a gallium nitride crystal is generated on the surface of boron nitride (i.e. the above-described inner wall surface or member surface), so that the surface is gradually covered, the amount of boron dissolved in the mixed melt liquid 24 from covered boron nitride is gradually reduced (boron reducing step). Further, with growth of the acicular seed crystal 40, the surface area of the crystal is increased, so that the density at which boron is entrapped in the acicular seed crystal 40 is decreased (boron reducing step).

In (i) and (ii), boron is dissolved in the mixed melt liquid 24 using a substance containing boron, but the method for dissolving boron in the mixed melt liquid 24 is not limited thereto, and other methods may be used, such as a method in which boron is added in the mixed melt liquid 24.

Preparation of Raw Material etc. and Crystal Growth Conditions

Operations to charge the reaction vessel 12 with a raw material etc. are carried out with the internal vessel 11 placed in, for example, a glove box made to have an inert gas atmosphere such as that of an argon gas.

In the case where the acicular seed crystal 40 is produced in the method (i), the reaction vessel 12 having the configuration described above in (i) is charged with the substance containing boron as described above in (i), a substance to be used as a flux, and a raw material.

In the case where a crystal of the acicular seed crystal 40 is produced in the method (ii), the reaction vessel 12 having the configuration described above in (ii) is charged with a substance to be used as a flux, and a raw material.

As the substance to be used as a flux, sodium or a sodium compound (e.g. sodium azide) is used, but as other examples, other alkali metals such as lithium and potassium, or compounds of such alkali metals may be used. Alkali earth metals such as barium, strontium and magnesium, or compounds of such alkali earth metals may also be used. A plurality of kinds of alkali metals or alkali earth metals may also be used.

As the raw material, gallium is used, but as examples of other raw materials, the reaction vessel 12 may be charged with other group 13 elements such as boron, aluminum, and indium or a mixture thereof as a raw material.

In this embodiment, a case has been described where the reaction vessel 12 has a configuration including boron, but the reaction vessel 12 does not necessarily have the configuration including boron, but may have a configuration including at least one of B, Al, O, Ti, Cu, Zn and Si.

After the raw material etc. is set as described above, the heater 13 is energized to heat the internal vessel 11 and the reaction vessel 12 therein to a crystal growth temperature. Then, in the reaction vessel 12, the substance to be used as a flux and the raw material etc. are melted to form the mixed melt liquid 24. By bringing nitrogen at the above-described partial pressure into contact with the mixed melt liquid 24 to dissolve the nitrogen in the mixed melt liquid 24, nitrogen as a raw material of the acicular seed crystal 40 can be supplied into the mixed melt liquid 24. Further, boron is dissolved in the mixed melt liquid 24 as described above (boron dissolving step) (mixed melt liquid forming step).

A crystal nucleus of the acicular seed crystal 40 is generated from the raw material and boron which are melted in the mixed melt liquid 24 at the inner wall of the reaction vessel 12. The raw material and boron in the mixed melt liquid 24 are supplied to the crystal nucleus, so that the crystal nucleus is grown, leading to growth of the acicular seed crystal 40. As described above, boron in the mixed melt liquid 24 is entrapped in the crystal (boron adding step) in the process of crystal growth of the acicular seed crystal 40, so that a region with a high boron concentration is easily generated on the inner side of the acicular seed crystal 40, and the acicular seed crystal 40 is easily elongated in the c-axis direction. When boron entrapped in the crystal is reduced (boron reducing step) as the concentration of boron in the mixed melt liquid 24 decreases, a region with a low boron concentration is easily generated on the outer side, and the acicular seed crystal 40 is hard to be elongated in the c-axis direction and is easily grown in the m-axis direction.

The nitrogen partial pressure in the internal vessel 11 is preferably in a range of 5 MPa to 10 MPa.

The temperature (crystal growth temperature) of the mixed melt liquid 24 is preferably in a range of 800° C. to 900° C.

As a preferred embodiment, it is preferable that the ratio of a mol number of an alkali metal to the total mol number of gallium and the alkali metal (e.g. sodium) is in a range of 75% to 90%, the crystal growth temperature of the mixed melt liquid 24 is in a range of 860° C. to 900° C., and the nitrogen partial pressure is in a range of 5 MPa to 8 MPa.

As a further preferred embodiment, it is preferable that the molar ratio of gallium and an alkali metal is 0.25:0.75, the crystal growth temperature is in a range of 860° C. to 870° C., and the nitrogen partial pressure is in a range of 7 MPa to 8 MPa.

By passing through the above-described steps, the acicular seed crystal 40 to be used for production of the bulk crystal 41 is obtained.

(2) Method for Production of Bulk Crystal Used for Seed Crystal

Next, a method for producing the bulk crystal 41 from the acicular seed crystal 40 using a flux method will be described in detail.

As illustrated in FIG. 5, the bulk crystal 41 is a crystal produced by crystal-growing a nitride crystal in the acicular seed crystal 40. In this embodiment, a nitride crystal is crystal-grown in the acicular seed crystal 40 within the reaction vessel using a flux method.

FIG. 6 is a schematic view illustrating one example of a production apparatus 2 for producing the bulk crystal 41. Members and materials same as those in the production apparatus 1 are given the same reference numerals, and detailed descriptions thereof may not be repeated.

The production apparatus 2 includes an external pressure-resistant vessel 50 made of stainless steel. An internal vessel 51 is placed in the external pressure-resistant vessel 50, and further a reaction vessel 52 is stored in the internal vessel 51, thus forming a double structure. The internal vessel 51 is detachably attachable to the external pressure-resistant vessel 50.

The reaction vessel 52 is a vessel which holds the acicular seed crystal 40 and the mixed melt liquid 24, and is intended for crystal-growing the bulk crystal 41 from the acicular seed crystal 40.

The material of the reaction vessel 52 is not particularly limited, and a BN sintered body, a nitride such as P—BN, an oxide such as alumina or YAG, a carbide such as SiC, or the like is used. The inner wall surface of the reaction vessel 52, i.e. a site at which the reaction vessel 52 is in contact with the mixed melt liquid 24, is desired to be formed of a material that hardly reacts with the mixed melt liquid 24. Examples of the material which enables gallium nitride to be crystal-grown includes nitrides such as boron nitride (BN), pyrolytic BN(P—BN) and aluminum nitride, oxides such as alumina and yttrium/alumina/garnet (YAG), and stainless steel (SUS).

A gas supply pipe 65 and a gas supply pipe 66 for supplying a nitrogen (N₂) gas as a raw material of the bulk crystal 41 and a diluent gas for adjustment of total pressure to an internal space 67 of the external pressure-resistant vessel 50 and an internal space 68 of the internal vessel 51 are connected to the external pressure-resistant vessel 50 and the internal vessel 51. A gas supply pipe 54 is branched into a nitrogen supply pipe 57 and a gas supply pipe 60, which can be isolated by valves 55 and 58, respectively.

It is desirable to use as a diluent gas an argon (Ar) gas which is an inert gas, but the diluent gas is not limited thereto, and other inert gases such as helium (He) may be used as the diluent gas.

The nitrogen gas is supplied from the nitrogen supply pipe 57 connected to a gas cylinder etc. of nitrogen gas, pressure-adjusted in a pressure controller 56, and then supplied to the gas supply pipe 54 through the valve 55. On the other hand, the total pressure adjusting gas (e.g. argon gas) is supplied from the total pressure adjusting gas supply pipe 60 connected to a gas cylinder etc. of total pressure adjusting gas, pressure-adjusted in a pressure controller 59, and supplied to the gas supply pipe 54 through the valve 58. In this way, the pressure-adjusted nitrogen gas and total pressure adjusting gas are each supplied to the gas supply pipe 54 and mixed.

The mixed gas of nitrogen and diluent gas is supplied from the gas supply pipe 54 through a valve 63, the gas supply pipe 65, a valve 61, and the gas supply pipe 66 into the external pressure-resistant vessel 50 and the internal vessel 51. The internal vessel 51 can be detached from the production apparatus 2 at the location of the valve 61. The gas supply pipe 65 communicates with the outside through the valve 62.

The gas supply pipe 54 is provided with a pressure gauge 64, so that the pressures of the insides of the external pressure-resistant vessel 50 and the internal vessel 51 can be adjusted while the total pressures of the insides of the external pressure-resistant vessel 50 and the internal vessel 51 are monitored by the pressure gauge 64.

In this embodiment, a nitrogen partial pressure can be adjusted by adjusting the pressures of the nitrogen gas and the diluent gas by the valves 55 and 58 and the pressure controllers 56 and 59. Since the total pressures of the external pressure-resistant vessel 50 and the internal vessel 51 can be adjusted, the total pressure in the internal vessel 51 increases, and evaporation of a flux (e.g. sodium) in the reaction vessel 52 can be suppressed. That is, a nitrogen partial pressure associated with a nitrogen raw material, which has influences on crystal growth conditions of gallium nitride, and a total pressure having influences on suppression of evaporation of a flux such as sodium can be controlled separately. The flux is similar to the flux used during formation of the acicular seed crystal 40.

As illustrated in FIG. 6, a heater 53 is placed on the outer periphery of the internal vessel 51 in the external pressure-resistant vessel 50. The heater 53 heats the internal vessel 51 and the reaction vessel 52 to adjust the temperature of the mixed melt liquid 24.

Operations to charge the reaction vessel 52 with a raw material etc. such as the acicular seed crystal 40, Ga, Na, an additive such as C and a dopant such as Ge are carried out with the internal vessel 51 placed in, for example, a glove box in an inert gas atmosphere such as that of an argon gas. The operations may be carried out with the reaction vessel 52 placed in the internal vessel 51.

The acicular seed crystal 40 is placed in the reaction vessel 52. The reaction vessel 52 is charged with a substance containing at least a group 13 metal (e.g. gallium) and a substance to be used as the flux described above. In this embodiment, a case is described where Na, which is an alkali metal, is used as a flux, but the flux is not limited to Na.

In this embodiment, a case is described where a gallium, which is a group 13 metal, is used as a substance containing a group 13 metal, which is a raw material. As the group 13 metal, other group 13 metals such as boron, aluminum, and indium may be used, or a mixture of a plurality of metals selected from group 13 metals may be used.

The molar ratio of a group 13 metal and an alkali metal is not particularly limited, but the molar ratio of the alkali metal to a total mol number of the group 13 metal and the alkali metal is preferably 40% to 95%.

After the raw material etc. is placed as described above, the heater 53 is energized to heat the internal vessel 51 and the reaction vessel 52 in the internal vessel 51 to a crystal growth temperature. Then, in the reaction vessel 52, the group 13 metal as a raw material, the alkali metal, and other additives etc. are melted to form the mixed melt liquid 24. By bringing nitrogen at the above-described partial pressure into contact with the mixed melt liquid 24 to dissolve the nitrogen in the mixed melt liquid 24, nitrogen as a raw material of the bulk crystal 41 is supplied into the mixed melt liquid 24 (dissolving step).

Then, the raw material dissolved in the mixed melt liquid 24 is supplied to the outer peripheral surface of the acicular seed crystal 40, so that the bulk crystal 41 is crystal-grown from the outer peripheral surface of the acicular seed crystal 40 by the raw material (crystal growth step).

In this step, a case has been described where a crystal is grown using the acicular seed crystal 40 as a seed crystal, but instead of the acicular seed crystal 40, a later-described seed crystal 46 may be crystal grown as a seed crystal.

[2] Processing of Seed Crystal

The bulk crystal 41 produced in the production apparatus 2 is processed so that the cross-section shape crossing the c-axis is non-hexagonal. Specifically, for the bulk crystal 41, cutting processing along a direction parallel to the c-axis is performed in a direction crossing the c-axis at each predetermined interval, so that the cross-section shape crossing the c-axis is non-hexagonal.

FIGS. 7(A) and 7(B) are explanatory views of processing of the bulk crystal 41. As illustrated in FIG. 7(A), for the bulk crystal 41, the bulk crystal 41 is cut along a plurality of cutting sections (sections shown by dotted-lines 42 in FIG. 7(A)) along a direction parallel to the c-axis. The cutting method may be a mechanical method or may be a chemical method, and a publicly known method may be used.

FIG. 7(B) is a schematic diagram of the c-plane cross section of the bulk crystal 41. As illustrated in FIG. 7(B), the bulk crystal 41 is cut in a direction parallel to the c-axis at each predetermined interval in mutually orthogonal two directions in a-plane along the c-axis (directions shown by dotted-lines 42A and 42B). By this cutting, the bulk crystal 41 is divided into a plurality of seed crystals 46 (first region 25A).

The seed crystal 46 to be used for production of the group 13 nitride crystal 25 is preferably one situated nearer the outside at the c-plane cross section of the bulk crystal 41 among a plurality of seed crystals 46 obtained by cutting (processing) the bulk crystal 41 in the plurality of the directions.

[3] Method for Production of Group 13 Nitride Crystal

Next, a method for producing the group 13 nitride crystal 25 from the seed crystal 46 using a flux method will be described in detail.

Production Apparatus

Next, a method for production of the group 13 nitride crystal 25 using a flux method will be described.

FIGS. 8(A), 8(B), and 8(C) are schematic views illustrating the outline of a method for production of the group 13 nitride crystal 25.

A crystal growth step in the method for production of the group 13 nitride crystal 25 includes a pre-growth step (see FIG. 8(A)), a first step (see FIG. 8(B)) and a second step (see FIG. 8(C)) in this order.

In the pre-growth step (see FIG. 8(A)), the bulk crystal 41 processed so that the cross-section shape crossing the c-axis is non-hexagonal (quadrangular in FIG. 8), i.e. the seed crystal 46 is placed in the reaction vessel 52 which holds the mixed melt liquid 24. The method for placing the seed crystal 46 in the reaction vessel 52 is not particularly limited, but for example, one end of the seed crystal 46 in the longitudinal direction is supported by a support member 47 placed on the bottom of the inside of the reaction vessel 52.

Preferably the seed crystal 46 is placed at the central part of a cross section perpendicular to the c-axis on the bottom of the reaction vessel 52 for producing the group 13 nitride crystal 25 of higher quality.

In the first step (see FIG. 8(B)), the second region 25B as a crystal transition region is grown from the seed crystal 46 (i.e. first region 25A). In the first step of growing the second region 25B, the mixed melt liquid 24 is not mechanically stirred.

In the second step (see FIG. 8(C)), the third region 25C is grown from the second region 25B while the mixed melt liquid 24 is mechanically stirred. For the method for mechanically stirring the mixed melt liquid 24, any publicly known stirring method may be used, and the method is not limited.

For example, as illustrated in FIG. 8(C), the reaction vessel 52 is configured to include a rotation mechanism which rotates the reaction vessel 52 with the c-axis of the group 13 nitride crystal 25 as a rotation axis (see the arrowed line A in FIG. 8(C)). The reaction vessel 52 may be rotationally driven to rotate the mixed melt liquid 24 held in the reaction vessel 52. As illustrated in FIG. 8(C), the reaction vessel 52 is configured to include a rocking mechanism which rocks the reaction vessel 52 in a predetermined direction (direction of the arrowed line B in FIG. 80). The reaction vessel 52 may be rocked to rotate the mixed melt liquid 24 held in the reaction vessel 52.

Next, a production apparatus to be used for production of the group 13 nitride crystal 25 will be described in detail.

For producing the group 13 nitride crystal 25 from the seed crystal 46 of the first region 25A, for example the production apparatus 2 described above is used (see FIG. 6). For production of the group 13 nitride crystal 25, the seed crystal 46 obtained by processing of the bulk crystal 41 (see FIG. 7) is used as the seed crystal instead of the acicular seed crystal 40.

In the production apparatus 2, the pressures of a nitrogen gas and a diluent gas are adjusted by valves 55 and 58 and pressure controllers 56 and 59 as described above. Thus, the nitrogen partial pressure such as a nitrogen partial pressure P1 in the first step and a nitrogen partial pressure P2 in the second step can be adjusted. Since the total pressures of the external pressure-resistant vessel 50 and the internal vessel 51 can be adjusted, the total pressure in the internal vessel 51 increases, and evaporation of an alkali metal (e.g. sodium) in the reaction vessel 52 can be suppressed. That is, a nitrogen partial pressure associated with a nitrogen raw material, which has influences on crystal growth conditions of gallium nitride, and a total pressure having influences on suppression of evaporation of sodium can be controlled separately.

As described above, the heater 53 is placed on the outer periphery of the internal vessel 51 in the external pressure-resistant vessel 50, so that the internal vessel 51 and the reaction vessel 52 can be heated to adjust the temperature of the mixed melt liquid 24. Thus, the heating temperature of the heater 53 is adjusted, so that a temperature T1 of the mixed melt liquid 24 in the first step and a temperature T2 in the second step fall within the range described above.

Preparation Of Raw Material etc. and Crystal Growth Conditions

Operations to charge the reaction vessel 52 with a raw material etc. such as the seed crystal 46, Ga, Na and a dopant such as C are carried out with the internal vessel 51 placed in, for example, a glove box in an inert gas atmosphere such as that of an argon gas. The operations may be carried out with the reaction vessel 52 placed in the internal vessel 51.

The seed crystal 46 is placed in the reaction vessel 52. The reaction vessel 52 is charged with a substance containing a group 13 element, i.e. a raw material, and a substance to be used as a flux as the mixed melt liquid 24.

As the substance to be used as a flux, sodium or a sodium compound (e.g. sodium azide) is used, but as other examples, other alkali metals such as lithium and potassium, or compounds of such alkali metals may be used. Alkali earth metals such as barium, strontium and magnesium, or compounds of such alkali earth metals may also be used. A plurality of kinds of alkali metals or alkali earth metals may also be used.

As the substance containing a group 13 element, i.e. a raw material, for example gallium that is a group 13 element is used, but as other examples, other group 13 elements such as boron, aluminum, and indium or a mixture thereof may be used.

The molar ratio of the substance containing a group 13 element and the alkali metal is not particularly limited, but the molar ratio of the alkali metal to a total mol number of the group 13 element and the alkali metal is preferably 40% to 95%.

After the raw material etc. is set as described above, the heater 53 is energized to heat the internal vessel 51 and the reaction vessel 52 in the internal vessel 51 to a crystal growth temperature. Then, in the reaction vessel 52, the substance containing a group 13 metal, i.e. a raw material, the alkali metal, and other additives etc are melted to form the mixed melt liquid 24. By bringing nitrogen at the above-described partial pressure into contact with the mixed melt liquid 24 to dissolve the nitrogen in the mixed melt liquid 24, nitrogen as a raw material of the group 13 nitride crystal 25 can be supplied into the mixed melt liquid 24.

The crystal growth occurs from the seed crystal 46, so that the group 13 nitride crystal 25 is produced (crystal growth step).

Specifically, the temperature and the nitrogen partial pressure are adjusted while mechanical stirring is not performed, so that the raw material melted in the mixed melt liquid 24 is supplied to the outer peripheral surface of the seed crystal 46, and the second region 25B as a transition region for crystal growth is formed from the outer peripheral surface of the seed crystal 46 by the raw material (first step).

Next, for example, as shown in FIGS. 9 and 10, a drive unit 70 is controlled by a control unit 72 that controls the production apparatus 2, and the reaction vessel 52 is rotated or rocked by driving of the drive unit 70 to adjust the temperature and the nitrogen partial pressure while mechanically stirring the mixed melt liquid 24, so that further the third region 25C is crystal-grown (second step).

FIG. 9 is a schematic view illustrating one example of rotational drive of the reaction vessel 52. As illustrated in FIG. 9, a support member 74 is placed on the outer peripheral surface of the reaction vessel 52. Then, the other end of the support member 74 is connected to the drive unit 70 that rotates the support member 74 with the longitudinal direction as a rotation axis. One end of the support member 74 is connected to the bottom of the outer peripheral surface of the reaction vessel 52 such that the longitudinal direction of the support member 74 coincides with the c-axis of the seed crystal 46 placed in the reaction vessel 52. The control unit 72 including a publicly known computer is connected to the drive unit 70 so as to be capable of transmitting and receiving signals.

By driving the drive unit 70 under control by the control unit 72, a drive force of the drive unit 70 is transmitted to the reaction vessel 52 through the support member 74, so that the reaction vessel 52 is rotated (direction of the arrowed line A in FIG. 9). The mixed melt liquid 24 held in the reaction vessel 52 is rotated with the rotation of the reaction vessel 52.

FIG. 10 is a schematic view illustrating one example of rocking drive of the reaction vessel 52. As illustrated in FIG. 10, a support member 76 is placed on the bottom of the outer peripheral surface of the reaction vessel 52. The other end of the support member 76 is held by a curved member 78 curved, which holds the support member 76 so as to be capable of rocking in a predetermined direction (see the arrowed line B in FIG. 10). The support member 76 is provided with the drive unit 70 for rocking the support member 76 along a longitudinal direction of the curved member 78. The drive unit 70 is connected to the control unit 72 so as to be capable of transmitting and receiving signals.

When the drive unit 70 is driven under control by the control unit 72, the support member 76 and the reaction vessel 52 held by the support member 76 are rocked in the direction of the arrowed line B along the longitudinal direction of the curved member 78. Consequently, the mixed melt liquid 24 in the reaction vessel 52 is rotated.

The method for mechanically stirring the mixed melt liquid 24 is not limited to the form illustrated in FIGS. 9 and 10, and a publicly known method may be used.

As described above, the third region 25C is crystal-grown after crystal growth of the second region 25B from the outer peripheral surface of the seed crystal 46 by passing through the crystal growth step including the first step and the second step. Thus, the group 13 nitride crystal 25 can be produced.

FIG. 11 is a schematic diagram illustrating one example of the produced group 13 nitride crystal 25. As illustrated in FIG. 11, according to the above-described production method, the third region 25C is grown after the second region 25B is grown from the first region 25A, so that the group 13 nitride crystal 25 is produced.

Turning back to FIG. 6, as a preferred embodiment, the nitrogen gas partial pressure in the internal space 68 of the internal vessel 51 and the internal space 67 of the external pressure-resistant vessel 50 is preferably 0.1 MPa or more. As a more preferred embodiment, the nitrogen gas partial pressure (hereinafter, referred to simply as nitrogen partial pressure) in the internal space 68 of the internal vessel 51 and the internal space 67 of the external pressure-resistant vessel 50 is preferably in a range of 2 MPa to 5 MPa.

As a preferred embodiment, the temperature (crystal growth temperature) of the mixed melt liquid 24 is preferably 700° C. or higher. As a more preferred embodiment, the crystal growth temperature is preferably in a range of 850° C. to 900° C.

Further specifically, the temperature T1 of the mixed melt liquid 24 in the first step of crystal-growing the second region 25B is preferably lower than the temperature T2 of the mixed melt liquid 24 in the second step of crystal-growing the third region 25C. Specifically, it is preferable that the temperature T1 and the temperature T2 are in the above-described range (700° C. or higher), the temperature T1 of the mixed melt liquid 24 in the first step is lower by 10° C. or more, especially preferably by 20° C. or more, than the temperature T2 of the mixed melt liquid 24 in the second step.

The nitrogen partial pressure P1 in the first step of growing the second region 25B is preferably higher than the nitrogen partial pressure P2 in the second step of growing the third region 25C. Specifically, it is preferable that the nitrogen partial pressure P1 and the nitrogen partial pressure P2 are in the above-described range (in a range of 2 MPa to 5 MPa), and the nitrogen partial pressure P1 in the first step is higher by 0.4 NPa or more, especially preferably by 0.8 MPa or more, than the nitrogen partial pressure P2 in the second step.

As described above, the group 13 nitride crystal 25 of this embodiment includes the first region 25A, the second region 25B, and the third region 25C. The first region 25A is a region provided on the inner side of a cross section crossing the c-axis. The third region 25C is a region provided on the outermost side of the cross section. The second region 25B is a region which is provided between the first region 25A and the third region 25C at the cross section and has crystal characteristics different from those of the first region 25A and the third region 25C and in which the shape formed by a boundary with the first region 25A at the cross section is non-hexagonal.

Thus, in the group 13 nitride crystal 25 of this embodiment, the second region 25B is provided between the first region 25A on the inner side of a cross section crossing the c-axis and the third region 25C on the outermost side of the cross section in the group 13 nitride crystal 25. The second region 25B is a transition region for crystal growth. The cross-section shape crossing the c-axis in the first region 25A is non-hexagonal.

Therefore, the second region 25B is easily formed so as to cover the entire outer periphery of the first region 25A during production of the group 13 nitride crystal 25 of hexagonal crystal as compared to a case where the shape of the cross section in the first region 25A is hexagonal.

FIG. 12 is a schematic diagram illustrating one example of a comparative group 13 nitride crystal 250 where a first region 250A is hexagonal. In the case where the cross-section shape crossing the c-axis in the first region 250A is hexagonal, a region is generated in which a second region 250B is not formed between the first region 250A and a third region 250C as illustrated in FIG. 12.

On the other hand, for the group 13 nitride crystal 25 of this embodiment, the second region 25B is effectively formed on the periphery of the first region 25A during production of the group 13 nitride crystal 25. Therefore, it is considered that in this embodiment, a group 13 nitride crystal of high quality can be provided.

Further, preferably the first region 25A which is the seed crystal 46, and the second region 258 and the third region 25C are produced using the same crystal growth method (flux method). By producing these regions using the flux method, consistency between a lattice constant and a heat expansion coefficient can be improved and occurrence of dislocations can be easily suppressed as compared to a case where these regions are produced using different crystal growth methods.

A case has been described above where the seed crystal 46 and the group 13 nitride crystal 25 are crystal-grown using the flux method, but the crystal growth method is not particularly limited, and a vapor phase growth method such as a HVPE method, or a liquid phase method other than the flux method may be used. However, it is preferable to use the flux method for producing the group 13 nitride crystal 25 of high quality.

It suffices that the position of the first region 25A in the group 13 nitride crystal 25 is within the group 13 nitride crystal 25, and the first region 25A may be included at around the center of the group 13 nitride crystal 25 (at around the center of a cross section crossing the c-axis) as illustrated in FIG. 1, or may be situated at a position deviated from the center.

### Example 1

Examples will be shown below for describing the present invention further in detail, but the present invention is not limited to these Examples. The reference numerals correspond to the configurations of the production apparatuses 1 and 2 described with reference to FIG. 4 and FIG. 6.

Production of Seed Crystal

First, a seed crystal to be used for production of a group 13 nitride crystal was produced using the production method described below.

Example of Production of Acicular Seed Crystal 1

An acicular seed crystal 40 was produced using the production apparatus 1 illustrated in FIG. 4.

A reaction vessel 12 formed of a BN sintered body and having an inner diameter of 92 mm was charged with gallium with a nominal purity of 99.99999% and sodium with a nominal purity of 99.95% at a molar ratio of 0.25:0.75.

The reaction vessel 12 was placed in a internal vessel 11 under a high-purity Ar gas atmosphere in a glove box, and a valve 21 was closed to shield the inside of the reaction vessel 12 from the outside atmosphere, so that the internal vessel 11 was sealed while being filled with an Ar gas.

Thereafter, the internal vessel 11 was taken out from the glove box, and incorporated into the production apparatus 1. That is, the internal vessel 11 was placed at a predetermined position with respect to a heater 13, and connected to a gas supply pipe 14 for a nitrogen gas and an argon gas at the valve 21 part.

Next, the argon gas was purged from the internal vessel 11, a nitrogen gas was then introduced from a nitrogen supply pipe 17, and the pressure was adjusted by a pressure controller 16 to open a valve 15, so that the nitrogen pressure in the internal vessel 11 was 3.2 MPa. Thereafter, the valve 15 was closed, and the pressure controller 16 was set at 8 MPa. Then, the heater 13 was energized to heat the reaction vessel 12 to a crystal growth temperature. In Example 1, the crystal growth temperature was 870° C.

At the crystal growth temperature, gallium and sodium in the reaction vessel 12 were melted to form a mixed melt liquid 24. The temperature of the mixed melt liquid 24 was equal to the temperature of the reaction vessel 12. In the production apparatus 1 of this Example, when the temperature was elevated to the above-mentioned temperature, a gas in the internal vessel 11 was heated, so that the total pressure reached 8 MPa.

Next, the valve 15 was opened to achieve a nitrogen gas pressure of 8 MPa, so that a pressure equilibrium state was established between the inside of the internal vessel 11 and the inside of the nitrogen supply pipe 17.

In this state, the reaction vessel 12 was held for 500 hours to crystal-grow gallium nitride, and the heater 13 was then controlled to cool the internal vessel 11 to room temperature (about 20° C.). After the pressure of the gas in the internal vessel 11 was decreased, the internal vessel 11 was opened to find that a large number of acicular seed crystals 40 of gallium nitride were crystal-grown in the reaction vessel 12. The acicular seed crystal 40 was colorless and transparent, and had a crystal diameter d of about 100 to 1500 μm and a length L of about 10 to 40 mm, and the ratio of the length L to the crystal diameter d (L/d) was about 20 to 300. The acicular seed crystal was grown generally in parallel to the c-axis, and the m-plane was formed on the side surface. The cross section crossing the c-axis in the acicular seed crystal was hexagonal.

Example of Production of Bulk Crystal 1

In this Example, a bulk crystal 41 was produced by crystal-growing the bulk crystal 41 from the acicular seed crystal 40 using the production apparatus 2 illustrated in FIG. 6.

As the acicular seed crystal 40, the acicular seed crystal 40 produced in the Example of Production of Acicular Seed Crystal 1 was used. As the size of the acicular seed crystal 40, the maximum diameter of the c-plane was 1 mm and the length in the c-axis direction was about 40 mm.

First, an internal vessel 51 was separated from the production apparatus 2 at the valve 61 part, and placed in a globe box in an Ar atmosphere. Then, the acicular seed crystal 40 was placed in a reaction vessel 52 formed of alumina and having an inner diameter of 140 mm and a depth of 100 mm.

Next, as a flux, sodium (Na) was heated into a liquid, and put in the reaction vessel 52. After sodium was solidified, gallium was put in the vessel. In this Example, the molar ratio of sodium and gallium was 0.25:0.75.

Thereafter, the reaction vessel 52 was placed in the internal vessel 51 under a high-purity Ar gas atmosphere in the glove box. The valve 61 was closed to seal the internal vessel 51 filled with an Ar gas, so that the inside of the reaction vessel 52 was shielded from the outside atmosphere. Next, the internal vessel 51 was taken out from the glove box, and incorporated into the production apparatus 2. That is, the internal vessel 51 was placed at a predetermined position with respect to a heater 53, and connected to a gas supply pipe 54 at the valve 61 part.

Next, the argon gas was purged from the internal vessel 51, a nitrogen gas was then introduced from a nitrogen supply pipe 57, and the pressure was adjusted by a pressure controller 56 to open a valve 55, so that the total pressure in the internal vessel 51 was 1.2 MPa. Thereafter, the valve 55 was closed, and the pressure controller 56 was set at 3.0 MPa.

Next, the heater 53 was energized to heat the reaction vessel 52 to a crystal growth temperature. The crystal growth temperature was 870° C. As in the case of production in the Example of Production of Acicular Seed Crystal 1, the valve 55 was opened to achieve a nitrogen gas pressure of 3.0 MPa, and in this state, the reaction vessel 52 was held for 1500 hours to grow a gallium nitride crystal.

As a result, in the reaction vessel 52, the crystal diameter was increased in a direction perpendicular to the c-axis of the acicular seed crystal 40, and the bulk crystal 41 having a larger crystal diameter was grown. The bulk crystal 41 obtained through crystal growth was generally colorless and transparent and had a crystal diameter d of 51 mm, and the length L in the c-axis direction was about 54 mm including a part of seed crystal inserted in the reaction vessel. The shape of the bulk crystal 41 was a hexagonal pyramid shape in the upper part and a hexagonal prism shape in the lower part.

Processing of Bulk Crystal 41

For the bulk crystal 41 produced as described above, cutting along the c-axis was performed every 1000 μm in each two directions perpendicular to the c-axis using a multiwire saw. In this way, a seed crystal was produced in which the cross-section shape crossing the c-axis was quadrangular (size of cross section: 1000 μm×1000 μm, length in c-axis direction: 40 mm) (hereinafter, referred to a quadrangular prism seed crystal 46).

Similarly, for the bulk crystal 41, cutting along the c-axis was performed using a multiwire saw to produce the seed crystal 46 in which the cross-section shape crossing the c-axis was triangular (1000 μm (bottom line of cross section)×860 μm (height), length in c-axis direction: 40 mm) (hereinafter, referred to a triangular prism seed crystal 46).

Evaluation of Dislocation Density of First Region

The processed seed crystal 46 prepared as described above was cut so as to perpendicularly cross the c-axis, and the c-plane surface was observed with cathodoluminescenece. As an apparatus of cathodoluminescenece, MERLIN manufactured by Carl Zeiss Co., Ltd. was used, and the surface was observed at an accelerating voltage of 5.0 kV and a probe current of 4.8 nA and at room temperature.

The density of threading dislocations passing through the c-plane of the seed crystal 46 (used as first region 25A later) was 10² cm⁻² or less. This was calculated by counting spots observed as a dark spot with cathodoluminescenece of the c-plane. Here, in observation of c-plane cathodoluminescenece of a group 13 nitride crystal substrate, a dislocation that is not parallel to the c-axis or the c-plane such as one in the <11-23> direction is observed as a short line or the like if the dislocation exists on the c-plane surface. However, such a short line was not found on the c-plane of the seed crystal 46, and it could be confirmed that a dislocation that is not parallel to the c-axis or the c-plane hardly existed in the group 13 nitride gallium crystal of this embodiment. The basal plane dislocation density of the c-plane of the seed crystal 46 was 10′ cm⁻² to 10⁶ cm⁻², and it could be confirmed that the dislocation density of basal plane dislocations was higher than the dislocation density of threading dislocations.

Next, the group 13 nitride crystal 25 was produced using the seed crystal 46 produced by processing of the bulk crystal 41 by the above described crystal production method.

### Example 1

In this Example, a group 13 nitride crystal as one example of the group 13 nitride crystal 25 by crystal-growing the processed quadrangular prism seed crystal 46 (first region 25A) (see FIG. 1) using the production apparatus 2 illustrated in FIG. 6.

First, an internal vessel 51 was separated from the production apparatus 2 at the valve 61 part, and placed in a glove box in an Ar atmosphere. Then, the quadrangular prism seed crystal 46 was placed in a reaction vessel 52 formed of alumina and having an inner diameter of 140 mm and a depth of 100 mm. A hole having a depth of 4 mm was drilled in the bottom of the reaction vessel 52, and the quadrangular prism seed crystal 46 was inserted through the hole and held.

Next, sodium (Na) was heated into a liquid, and put in the reaction vessel 52. After sodium was solidified, gallium was put in the vessel. In this Example, the molar ratio of sodium and gallium was 0.25:0.75.

Thereafter, the reaction vessel 52 was placed in the internal vessel 51 under a high-purity Ar gas atmosphere in the glove box. The valve 61 was closed to seal the internal vessel 51 filled with an Ar gas, so that the inside of the reaction vessel 52 was shielded from the outside atmosphere. Next, the internal vessel 51 was taken out from the glove box, and incorporated into the production apparatus 2. That is, the internal vessel 51 was placed at a predetermined position with respect to a heater 53, and connected to a gas supply pipe 54 at the valve 61 part.

Next, the argon gas was purged from the internal vessel 51, a nitrogen gas was introduced from a nitrogen supply pipe 57, and the pressure was adjusted by a pressure controller 56 to open a valve 55, so that the total pressure in the internal vessel 51 was 1.2 MPa. Thereafter, the valve 55 was closed, and the pressure controller 56 was set at 3.2 MPa.

Next, the heater 53 was energized to heat the reaction vessel 52 to a crystal growth temperature. The crystal growth temperature was 870° C.

As a first step, with the temperature T1 of a mixed melt liquid 24 kept at 870° C., the valve 55 was opened to achieve a nitrogen partial pressure P1 of 3.2 MPa, and in this state, the reaction vessel 52 was held for 60 hours to grow a gallium nitride crystal (second region 25B).

Next, as a second step, the reaction vessel 52 was rotationally driven to rotate the mixed melt liquid 24, and with the temperature T2 of the mixed melt liquid 24 kept at 870° C., a nitrogen partial pressure P2 of 3.2 MPa was achieved, and the reaction vessel 52 was held for 1440 hours to grow a gallium nitride crystal (third region 25C).

As a result, in the reaction vessel 52, the crystal diameter was increased in a direction perpendicular to the c-axis of the seed crystal 46, and the group 13 nitride crystal 25 (single crystal) having a larger crystal diameter was grown. The group 13 nitride crystal 25 obtained through crystal growth was generally colorless and transparent and had a crystal diameter d of 51 mm, and the length L in the c-axis direction was about 54 mm including a part of seed crystal inserted in the reaction vessel. The shape of the group 13 nitride crystal 25 was a hexagonal pyramid shape in the upper part and a hexagonal prism shape in the lower part.

When only the temperature was made different between the first step and the second step and when only the pressure was made different between the first step and the second step, similar results were obtained.

That is, as a first step, with the temperature T1 of the mixed melt liquid 24 kept at 850° C., the valve 55 was opened to achieve a nitrogen partial pressure P1 of 3.2 MPa, and in this state, the reaction vessel 52 was held for 60 hours to grow a gallium nitride crystal (second region 258).

Next, as a second step, the reaction vessel 52 was rotationally driven to rotate the mixed melt liquid 24, and with the temperature T2 of the mixed melt liquid 24 kept at 870° C., a nitrogen partial pressure P2 of 3.2 MPa was achieved, and the reaction vessel 52 was held for 1440 hours to grow a gallium nitride crystal (third region 25C). In this case, a result similar to that described above was obtained.

As a first step, with the temperature T1 of the mixed melt liquid 24 kept at 870° C., the valve 55 was opened to achieve a nitrogen partial pressure P1 of 4.0 MPa, and in this state, the reaction vessel 52 was held for 60 hours to grow a gallium nitride crystal (second region 25B).

Next, as a second step, the reaction vessel 52 was rotationally driven to rotate the mixed melt liquid 24, and with the temperature T2 of the mixed melt liquid 24 kept at 870° C., a nitrogen partial pressure P2 of 3.2 MPa was achieved, and the reaction vessel 52 was held for 1440 hours to grow a gallium nitride crystal (third region 25C).

In this case, a result similar to that described above was obtained.

### Example 2

In this Example, a group 13 nitride crystal as one example of the group 13 nitride crystal 25 was produced by crystal-growing a seed crystal 46 using the production apparatus 2 illustrated in FIG. 6 under the same conditions as in Example 1 except that the triangular prism seed crystal 46 produced as described above was used as the seed crystal 46.

The group 13 nitride crystal obtained in Example 2 had a hexagonal pyramid shape in the upper part and a hexagonal prism shape in the lower part like the group 13 nitride crystal obtained in Example 1.

### Comparative Example 1

In this Comparative Example, a comparative group 13 nitride crystal was produced by performing crystal growth using the production apparatus 2 illustrated in FIG. 6 under the same conditions as in Example 1 except that an acicular seed crystal 40 (the cross-section shape crossing the c-axis is hexagonal) was used as a seed crystal 46.

Evaluation

Result of Measurement of Photoluminescence (PL)

The c-plane (cross section perpendicular to the c-axis) of each of the group 13 nitride crystals produced in Example 1 and Example 2 and Comparative Example I described above was photographed with photoluminescence, and a crystal state was observed.

As a result, it was confirmed that for the group 13 nitride crystals produced in Example 1 and Example 2, the first region 25A, the second region 25B, and the third region 25C were formed in this order toward the outer side from the inner side of the c-plane, and the entire outer periphery of the first region 25A was covered with the second region 25B. That is, it could be confirmed that for the group 13 nitride crystals produced in Example 1 and Example 2, the second region 258 lay over the entire region between the first region 25A and the third region 25C.

The second region 25B had many dark line parts and some defects and dislocations in a large amount as compared to the first region 25A and the third region 25C.

On the other hand, for the group 13 nitride crystal produced in Comparative Example 1, the first region 25A, the second region 258, and the third region 25C were formed in this order toward the outer side from the inner side of the c-plane, but a part of the outer periphery of the first region 25A had a region where the second region 25B was not provided.

Evaluation of Dislocation Density

The cross section parallel to the c-axis and the a-axis of each of the group 13 nitride crystals produced in each of Example 1 and Example 2 and Comparative Example 1 described above was observed with cathodoluminescenece.

As a result, it could be confirmed that in the group 13 nitride crystals produced in Example 1 and Example 2 described above, there were larger number of dark lines corresponding to dislocations in a direction crossing the c-axis in the second region 25B than in the first region 25A and the third region 25C.

Similarly, the dislocation density C of the third region 25C and the dislocation density M of the m-plane of the third region 25C for each of the group 13 nitride crystals produced in each of Example 1 and Example 2 described above were measured in the same manner as described above.

As a result, the dislocation density C of the third region 25C was lower than the dislocation density M of the m-plane of the third region 25C in the group 13 nitride crystals produced in Example 1 and Example 2 described above. The ratio of the dislocation density C and the dislocation density M (M/C) was higher than 1000.

On the other hand, when the dislocation density of the third region 25 C of the group 13 nitride crystal produced in Comparative Example 1 was measured, it was 10′ cm⁻² to 10⁹ cm⁻², and the dislocation density maximum value was approximately double as compared to Example. Therefore, it could be confirmed that the group 13 nitride crystal produced in Example 1 and Example 2 had high quality as compared to the group 13 nitride crystal produced in Comparative Example 1. According to the present invention, a group 13 nitride crystal of high quality can be obtained.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A group 13 nitride crystal of hexagonal crystal comprising at least one or more metal atom selected from the group consisting of B, Al, Ga, In, and Tl, and a nitrogen atom, the group 13 nitride crystal comprising:
a first region provided on the inner side of a cross section crossing a c-axis;
a third region provided on an outermost side of the cross section;
a second region provided between the first region and the third region at the cross section and having characteristics different from characteristics of the first region and the third region,
wherein a shape formed by a boundary between the first region and the second region at the cross section is non-hexagonal.

2. The group 13 nitride crystal according to claim 1, wherein
the second region is provided, at the cross section, so as to cover an entire outer periphery of the first region, and the first region and the third region are in a non-contact state.

3. The group 13 nitride crystal according to claim 1, wherein
the dislocation density of dislocations in a direction crossing the c-axis in the second region is higher than the dislocation density of dislocations in a direction crossing the c-axis in the first region and the third region.

4. The group 13 nitride crystal according to claim 1, wherein
the dislocation density of basal plane dislocations in the first region is higher than the dislocation density of threading dislocations of a c-plane in the first region.

5. A method for production of a group 13 nitride crystal, the method comprising a crystal growth step of crystal-growing a nitride crystal on a seed crystal whose cross-section shape crossing a c-axis is non-hexagonal.

6. The method for production of a group 13 nitride crystal according to claim 5, wherein
the seed crystal is produced by processing a group 13 nitride crystal obtained by crystal-growing an acicular seed crystal.

7. The method for production of a group 13 nitride crystal according to claim 5, wherein
the seed crystal is a crystal obtained by cutting a group 13 nitride crystal, in which the dislocation density of basal plane dislocations is higher than the dislocation density of threading dislocations of the c-plane, in a direction parallel to the c-axis.

8. The method for production of a group 13 nitride crystal according to claim 5, wherein
the cross-section shape of the seed crystal crossing the c-axis is quadrangular.

9. The method for production of a group 13 nitride crystal according to claim 5, wherein
the crystal growth step is a step of crystal-growing a nitride crystal on the seed crystal by reacting a mixed melt liquid with nitrogen in the mixed melt liquid containing at least one of an alkali metal and an alkali earth metal and at least a group 13 metal.

10. The method for production of a group 13 nitride crystal according to claim 9, wherein
the crystal growth step includes the steps of:
growing a second region as a crystal transition region from the seed crystal without stirring the mixed melt liquid; and
growing a third region from the second region while stirring the mixed melt liquid.

11. The method for production of a group 13 nitride crystal according to claim 9, wherein
the crystal growth step includes the steps of:
growing a second region as a crystal transition region from the seed crystal with the temperature of the mixed melt liquid being a temperature T1; and
growing a third region from the second region with the temperature of the mixed melt liquid being a temperature T2,
wherein T1 is lower than T2.

12. The method for production of a group 13 nitride crystal according to claim 9, wherein
the crystal growth step includes the steps of:
growing a second region as a crystal transition region from the seed crystal with the nitrogen partial pressure being a nitrogen partial pressure P1; and
growing a third region from the second region with the nitrogen partial pressure being a nitrogen partial pressure P2,
wherein P1 is higher than P2.
